(19) United States
(12) Patent Application Publication
(10) Pub. No.: US 2025/0125175 A1
(43) Pub. Date: Apr. 17, 2025

(54) SUBSTRATE PROCESSING APPARATUS

(71) Applicant: Tokyo Electron Limited, Tokyo (JP)

(72) Inventors: Seiji Nakashima, Koshi City (JP); Tsuyoshi Watanabe, Koshi City (JP); Akira Oozono, Koshi City (JP); Suguru Enokida, Koshi City (JP)

(21) Appl. No.: 18/914,666

(22) Filed: Oct. 14, 2024

(30) Foreign Application Priority Data
Oct. 16, 2023 (JP) 2023-178375
Aug. 7, 2024 (JP) 2024-130942

(51) Int. Cl. H01L 21/677; H01L 21/67

(52) U.S. Cl. CPC H01L 21/67706; H01L 21/67173; H01L 21/67178

(57) ABSTRACT

A substrate processing apparatus includes a carry-in/out block having a container placement section; and a processing block, disposed to be adjacent to the carry-in/out block in a width direction, having multiple processing modules each configured to perform a process on a substrate. The carry-in/out block further includes: a transit block in which transit modules are provided on a processing block side to deliver the substrate to/from the processing block; and a first transfer mechanism configured to transfer the substrate between the container placement section and the transit block. The processing block further includes a second transfer mechanism configured to transfer the substrate between the transit block and the processing module. The first transfer mechanism has a support, and is configured to allow the substrate supported by the support to pass through the transit block in a depth direction intersecting with the width direction, when viewed from a top.

### CROSS-REFERENCE TO RELATED APPLICATION

This application claims the benefit of Japanese Patent Application Nos. 2023-178375 and 2024-130942 filed on Oct. 16, 2023 and Aug. 7, 2024, respectively, the entire disclosures of which are incorporated herein by reference.

### TECHNICAL FIELD

The various aspects and embodiments described herein pertain generally to a substrate processing apparatus.

### BACKGROUND

A coating and developing apparatus disclosed in Patent Document 1 forms a coating film including a resist film on a substrate carried into a carrier block by a carrier, transfers the substrate to an exposure apparatus through an interface block, performs a developing process on the exposed substrate returned through the interface block, and then transfers the substrate back into the carrier block. The coating and developing apparatus includes a processing block. The processing block includes a unit block for the coating film formation, and a unit block for the developing process that is stacked on top of the unit block for the coating film formation. Each unit block is equipped with a liquid processing unit, a heating unit, a cooling unit, and a transfer device for transferring the substrate between the units. In addition, a transfer area for the substrate is formed in the unit block to connect the carrier block and the interface block. An area of the transfer area adjacent to the carrier block serves as a transit area for the substrate. A shelf unit having one or more transit stages is provided in this transit area.
Patent Document 1: Japanese Patent Laid-open Publication No. 2006-203075

### SUMMARY

In an exemplary embodiment, a substrate processing apparatus includes a carry-in/out block having a container placement section in which multiple containers each configured to accommodate therein a substrate are placed; and a processing block, disposed to be adjacent to the carry-in/out block in a width direction, having multiple processing modules each configured to perform a process on the substrate. The carry-in/out block further includes: a transit block in which transit modules configured to deliver the substrate are provided on a processing block side to deliver the substrate to/from the processing block; and a first transfer mechanism configured to transfer the substrate between the container placement section and the transit block. The processing block further includes a second transfer mechanism configured to transfer the substrate between the transit block and the processing module. The first transfer mechanism has a support configured to support the substrate, and is configured to allow the substrate supported by the support to pass through the transit block in a depth direction intersecting with the width direction, when viewed from a top.

The foregoing summary is illustrative only and is not intended to be any way limiting. In addition to the illustrative aspects, embodiments, and features described above, further aspects, embodiments, and features will become apparent by reference to the drawings and the following detailed description.

### BRIEF DESCRIPTION OF THE DRAWINGS

In the detailed description that follows, embodiments are described as illustrations only since various changes and modifications will become apparent to those skilled in the art from the following detailed description. The use of the same reference numbers in different figures indicates similar or identical items.

FIG. 1 is an explanatory diagram illustrating a schematic configuration of a coating and developing apparatus as a substrate processing apparatus according to an exemplary embodiment;

FIG. 2 is an explanatory diagram illustrating a schematic configuration of a front side of the coating and developing apparatus of FIG. 1;

FIG. 3 is an explanatory diagram schematically illustrating a configuration of a processing block;

FIG. 4 is an explanatory diagram illustrating a configuration of a processing block side of a cassette block;

FIG. 5 is an explanatory diagram for describing a size of the cassette block;

FIG. 6 is an explanatory diagram illustrating a configuration of an interface block;

FIG. 7 is an explanatory diagram illustrating a modification example of a transit block belonging to the cassette block;

FIG. 8 is an explanatory diagram illustrating a specific example of an upper layer belonging to an upper sub block of the processing block;

FIG. 9 is an explanatory diagram illustrating a specific example of the upper layer belonging to the upper sub block of the processing block;

FIG. 10 is an explanatory diagram illustrating a specific example of the upper layer belonging to the upper sub block of the processing block;

FIG. 11 is an explanatory diagram illustrating a specific example of the upper layer belonging to the upper sub block of the processing block;

FIG. 12 is an explanatory diagram illustrating a schematic configuration of a first modification example of the processing block;

FIG. 13 is an explanatory diagram illustrating a schematic configuration of a front side of the processing block of FIG. 12;

FIG. 14 is an explanatory diagram schematically illustrating a configuration of a division block;

FIG. 15 is an explanatory diagram illustrating an intermediate block;

FIG. 16 is an explanatory diagram illustrating a schematic configuration of a second modification example of the processing block;

FIG. 17 is an explanatory diagram illustrating a configuration of an intermediate block belonging to the processing block of FIG. 16;

FIG. 18 is an explanatory diagram illustrating a schematic configuration of a third modification example of the processing block; and

FIG. 19 is an explanatory diagram illustrating a configuration of a division block belonging to the processing block of FIG. 18.

### DETAILED DESCRIPTION

In the following detailed description, reference is made to the accompanying drawings, which form a part of the description. In the drawings, similar symbols typically identify similar components, unless context dictates otherwise. Furthermore, unless otherwise noted, the description of each successive drawing may reference features from one or more of the previous drawings to provide clearer context and a more substantive explanation of the current exemplary embodiment. Still, the exemplary embodiments described in the detailed description, drawings, and claims are not meant to be limiting. Other embodiments may be utilized, and other changes may be made, without departing from the spirit or scope of the subject matter presented herein. It will be readily understood that the aspects of the present disclosure, as generally described herein and illustrated in the drawings, may be arranged, substituted, combined, separated, and designed in a wide variety of different configurations, all of which are explicitly contemplated herein.

In a photolithography process in a manufacturing process for a semiconductor device or the like, a predetermined process is performed to form a resist pattern on a substrate such as a semiconductor wafer (hereinafter, simply referred to as “wafer”). The predetermined process includes, for example, a resist coating process of coating a resist liquid on the substrate to form a resist film, an exposure process of exposing the resist film in a preset pattern, and a developing process of developing the exposed resist film. Among these processes, the resist coating process, the developing process, and the like are performed in a coating and developing apparatus, which is a substrate processing apparatus equipped with various kinds of processing modules configured to perform various processes on the substrate and a transfer module configured to transfer the substrate.

High throughput is required for the substrate processing apparatus. In order to achieve the high throughput, it is necessary to increase the number of processing modules mounted in the substrate processing apparatus. However, such an increase of the number of the processing modules mounted in the substrate processing apparatus would result in enlargement of the apparatus. Specifically, the footprint of the apparatus may increase.

In this regard, exemplary embodiments provide a technique capable of suppressing the enlargement of the substrate processing apparatus that might accompany the high throughput.

Hereinafter, a substrate processing apparatus according to an exemplary embodiment will be described with reference to the accompanying drawings. In the present specification and drawings, parts having substantially the same functions and configurations will be assigned same reference numerals, and redundant descriptions thereof will be omitted.

### <Coating and Developing Apparatus>

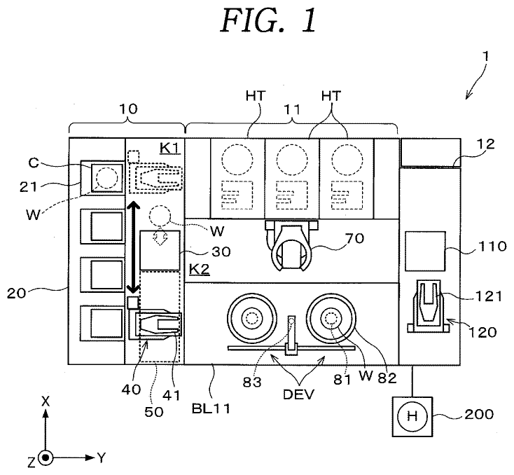

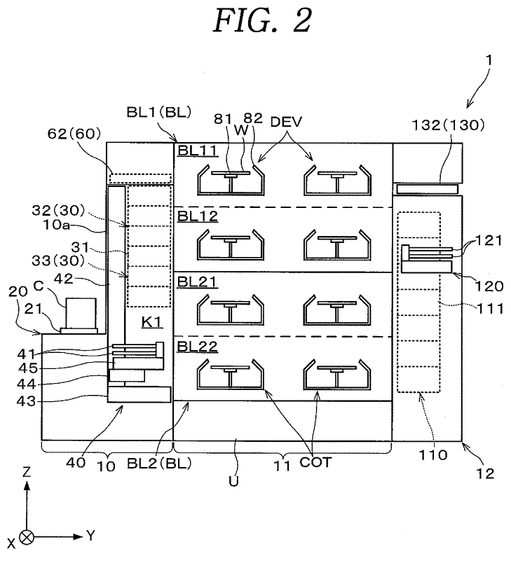

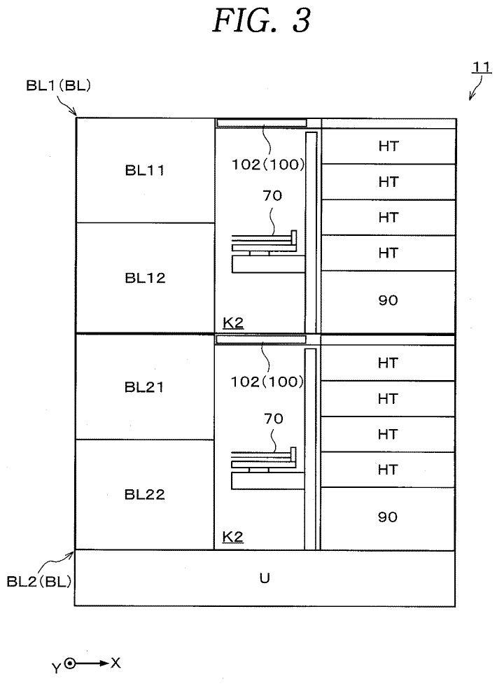

FIG. 1 is an explanatory diagram schematically illustrating a configuration of a coating and developing apparatus as a substrate processing apparatus according to an exemplary embodiment. FIG. 2 is an explanatory diagram schematically illustrating a configuration of a front side of the coating and developing apparatus of FIG. 1. FIG. 3 is an explanatory diagram schematically illustrating a configuration of a processing block to be described later. In addition, in FIG. 2, illustration of a storage section 50 to be described later is omitted.

A coating and developing apparatus 1 includes, as shown in FIG. 1 and FIG. 2, a cassette block 10 as a carry-in/out block, a processing block 11, and an interface block 12 as another block, and is connected to an exposure apparatus (not shown). The cassette block 10, the processing block 11, and the interface block 12 are arranged in this order in a width direction (Y-axis direction in the drawing), which is one direction in a horizontal direction, and are connected as one body. Further, the exposure apparatus is connected to a side of the interface block 12 opposite to the processing block 11. The exposure apparatus is configured to perform an exposure process on a wafer W.

Cassettes C, which are containers each configured to accommodate wafers W therein, are carried to/from the cassette block 10.

The cassette block 10 has a cassette placement table 20 as a container placement section on which the cassettes C are placed. In the cassette block 10, the cassette placement table 20 is provided at, for example, an end on one side (negative Y-axis side) in the width direction, that is, at an end on the opposite side to the processing block 11 in the width direction.

The cassettes C are arranged on the cassette placement table 20 in a depth direction (the X-axis direction in the drawing). Specifically, a plurality of (for example, four) placement plates 21 are provided on the cassette placement table 20 in a row in the depth direction, and the cassette C can be placed on each placement plate 21 when the cassette C is carried to/from the outside of the coating and developing apparatus 1. Here, the depth direction is a direction that intersects with the width direction (the Y-axis direction in the drawing) when viewed from the top, and, more specifically, is a direction perpendicular to the width direction when viewed from the top.

The placement plate 21 includes an elevating plate (not shown). The elevating plate elevates the wafers W in the cassette C placed on the placement plate 21 altogether into the cassette placement table 20, enabling the wafers W to be transferred to/from a first transfer mechanism 40 to be described later. The elevating plate is moved up and down between a first position at an upper side and a second position at a lower side by, for example, an elevating mechanism (not shown). The first position is a position where the wafer W on the elevating plate is located inside the cassette C, and the second position is a position where the wafer W is handed over between the elevating plate and the first transfer mechanism 40.

Further, depending on the diameter of the wafer W, it is specified by a standard that the wafer W is transferred between the cassette C and the first transfer mechanism 40 via the elevating plate as described above.

In addition, the cassette block 10 has a transit block 30. In the transit block 30, transit modules 31 configured to deliver the wafers W are stacked on top of each other. In the cassette block 10, the transit block 30 is provided on the processing block 11 side (positive Y-axis side) in the width direction for the delivery of the wafers W to/from the processing block 11. Specifically, the transit block 30 is provided in a portion of the cassette block 10 adjacent to a second transfer space K2 (to be described later) of the processing block 11 in the width direction (Y-axis direction in the drawing).

Furthermore, the cassette block 10 has the first transfer mechanism 40 configured to transfer the wafer W between the cassette placement table 20 and the transit block 30. The first transfer mechanism 40 has a fork 41 as a support configured to support the wafer W. The fork 41 is configured to be movable in a vertical direction (Z-axis direction in the drawing), around a vertical axis, in the depth direction (X-axis direction in the drawing), and in the width direction (Y-axis direction in the drawing).

The first transfer mechanism 40 is configured to allow the wafer W supported by the fork 41 to pass through the transit block 30 in the depth direction (X-axis direction in the drawing) when viewed from the top, as indicated by a thick arrow in black color in FIG. 1.

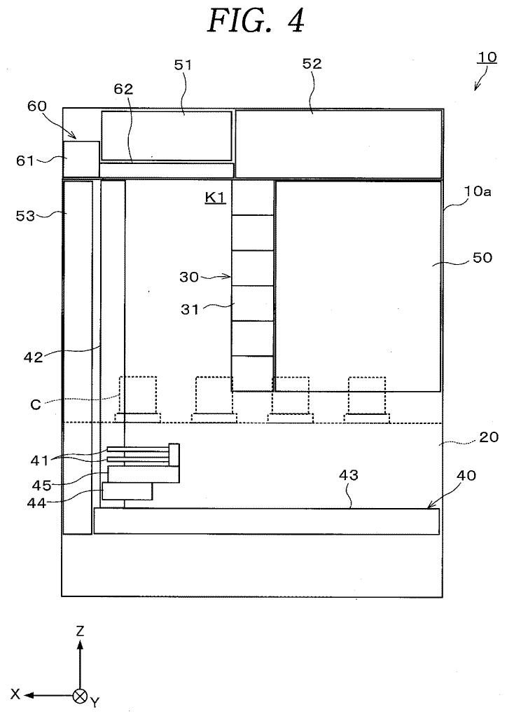

The cassette block 10 also has the storage section 50, as will be described later. Furthermore, as will be described later, the cassette block 10 is also provided with a first blower 60 (see FIG. 4).

A detailed configuration of the cassette block 10 will be described later.

The processing block 11 has a plurality of processing modules each configured to perform a predetermined process such as a developing process, and is provided adjacent to the cassette block 10 in the width direction (Y-axis direction in the drawing).

Further, the processing block 11 may further include a second transfer mechanism 70.

The second transfer mechanism 70 is configured to transfer the wafer W between the transit block 30 and the processing module within the processing block 11. The second transfer mechanism 70 may transfer the wafer W between the processing modules within the processing block 11. Further, in the present exemplary embodiment, the second transfer mechanism 70 also serves to transfer the wafer W between the processing module within the processing block 11 and a transit block 110 (to be described later) of the interface block 12.

This second transfer mechanism 70 transfers the wafer W to and from the transit block 30 in the width direction (Y-axis direction in the drawing).

For example, in the processing block 11, sub-blocks BL each provided with the second transfer mechanism 70 are stacked vertically, as illustrated in FIG. 3. In the shown example, two sub-blocks BL are stacked vertically. Hereinafter, the sub-block BL on the upper side may be referred to as an upper sub-block BL1, and the sub-block BL on the lower side may be referred to as a lower sub-block BL2.

At a center of each sub-block BL in the depth direction (X-axis direction), the second transfer space K2 provided with the second transfer mechanism 70 is formed so as to extend in the width direction (Y-axis direction) when viewed from the top.

Further, in each sub-block BL, a plurality of processing modules are arranged along the vertical direction (Z-axis direction in the drawing) and the width direction (Y-axis direction in the drawing) in a space on the front side (negative X-axis side in the drawing) of the second transfer space K2 and a space on the rear side (positive X-axis side in the drawing) of the second transfer space K2.

The space on the front side (negative X-axis side in the drawing) of the second transfer space K2 in the upper sub-block BL1 is divided into an upper layer BL11 and a lower layer BL12. As shown in FIG. 2, in each of the layers BL11 and BL12, a plurality of (two in the shown example) developing modules DEV are arranged along the width direction (Y-axis direction in the drawing).

The developing module DEV is configured to perform a developing process on the wafer W after being subjected to an exposure to develop a resist film on the wafer W, and forms a resist pattern. Each developing module DEV has a spin chuck 81 configured to hold and rotate the wafer W, and a cup 82 surrounding the wafer W on the spin chuck 81 and configured to collect a processing liquid scattered from the wafer W. Further, as shown in FIG. 1, a nozzle 83 is configured to discharge a developing liquid as the processing liquid onto the wafer W held by the spin chuck 81. For example, the single nozzle 83 is provided in each of the layers BL11 and BL12, and the nozzle 83 is shared by the developing modules DEV in the same layer.

As shown in FIG. 2, a space on the front side of the second transfer space K2 in the lower sub-block BL2 is also divided into an upper layer BL21 and a lower layer BL22, just like the upper sub-block BL1. In the lower sub-block BL2, however, a plurality of (two in the shown example) resist film forming modules COT are provided in each of the layers BL21 and BL22 along the width direction (Y-axis direction in the drawing).

The resist film forming module COT is configured to perform a resist film forming process on the wafer W to form the resist film on the wafer W. Each resist film forming module COT has a spin chuck 81 and a cup 82, like the developing module DEV. Also, a nozzle 83 is provided to be shared by the resist film forming modules COT in the same layer. A resist liquid configured to form the resist film is discharged as a processing liquid from the nozzle 83 of the resist film forming modules COT.

As illustrated in FIG. 1 and FIG. 3, in an upper space on the rear side (positive X-axis side in the drawing) of the second transfer space K2 in each sub-block BL, a plurality of (four in the example shown in FIG. 3) heat treatment modules HT are arranged along the vertical direction (Z-axis direction in the drawing), and, also, a plurality of (three in the example shown in FIG. 1) heat treatment modules HT are arranged along the width direction (Y-axis direction in the drawing). For example, each heat treatment module HT is configured to perform a heating process on the wafer W. Alternatively, each heat treatment module HT may be configured to perform both a heating process and a cooling process on the wafer W.

In addition, a storage section 90 is provided in a lower portion of the rear side of the second transfer space K2 in each sub-block BL. An electrical component (for example, a driver for controlling the heat treatment module HT, etc.) for the heat treatment module HT is accommodated in the storage section 90.

Furthermore, in the processing block 11, a utility section U is provided under the lower sub-block BL2. The utility section U functions as, for example, a storage section, and accommodates therein a component (such as a storage bottle for the resist liquid) related to the supply of the resist liquid into the resist film forming module COT.

Moreover, in the processing block 11, a filter 102 of a second blower 100 is provided for each sub-block BL.

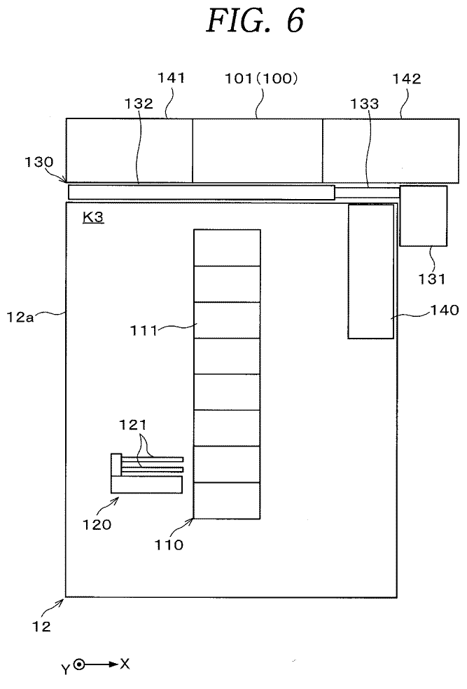

The second blower 100 is configured to supply a clean gas into the second transfer space K2 from above. The second blower 100 includes a fan device 101 (see FIG. 6) in addition to the filter 102.

The fan device 101 sends the gas to the filter 102. As a specific example, the fan device 101 draws in the gas and sends the drawn gas to the filter 102 via a duct (not shown). The fan device 101 is shared between the sub-blocks BL. The fan device 101 may be located on the interface block 12. That is, the fan device 101 may be stacked on top of the interface block 12.

The filter 102 purifies the gas sent from the fan device 101, that is, filters out particles in the gas, and discharges the purified gas (clean gas) towards the second transfer space K2 below.

The filter 102 is provided above the corresponding second transfer space K2.

In this way, a part of the second blower 100 (specifically, the fan device 101) is stacked on the interface block 12.

The interface block 12 is provided between the processing block 11 and the exposure apparatus (not shown) to transfer the wafer W therebetween.

The interface block 12 has, as illustrated in FIG. 1 and FIG. 2, the transit block 110. The transit block 110 is a stack of transit modules 111 configured to deliver the wafer W. In the interface block 12, the transit block 110 is provided on the processing block 11 side (negative Y-axis side in the drawing) in the width direction to deliver the wafer W to/from the processing block 11. Specifically, in the interface block 12, the transit block 110 is provided at a position adjacent to the second transfer space K2 of the processing block 11 in the width direction (Y-axis direction in the drawing).

In addition, the interface block 12 has a third transfer mechanism 120 configured to transfer the wafer W between the transit block 110 and the exposure apparatus. The third transfer mechanism 120 has a fork 121 configured to support the wafer W. The fork 121 is configured to be movable in the vertical direction (Z-axis direction in the drawing), around a vertical axis, in the depth direction (X-axis direction in the drawing), and in the width direction (Y-axis direction in the drawing).

Furthermore, the interface block 12 is also provided with a third blower 130, as will be described later.

A detailed configuration of the interface block 12 will be described later.

Further, the coating and developing apparatus 1 has a controller 200 configured to perform a control over the components of the coating and developing apparatus 1, including a control over the first to third transfer devices 40, 70 and 120. The controller 200 is, by way of example, a computer equipped with a processor such as a CPU and a memory, and has a program storage (not shown). The program storage stores a program including instructions for controlling the processing by the coating and developing apparatus 1. The program may be recorded on a computer-readable recording medium H, and may be installed from the recording medium H into the controller 200. The recording medium H may be transitory or non-transitory.

The controller 200 may be stored in a storage section 51 or 52 (to be described later) of the cassette block 10.

### <Cassette Block 10>

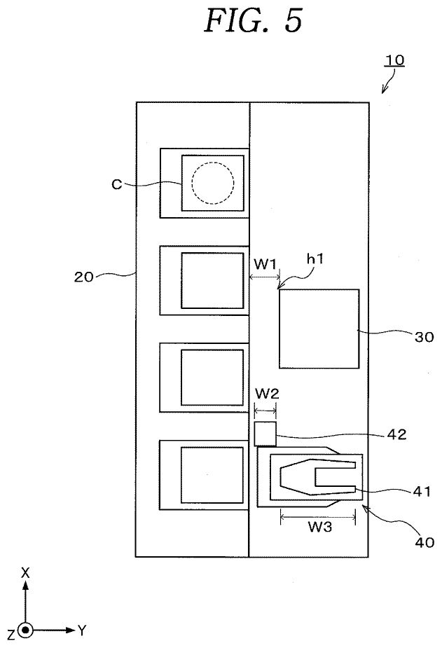

Now, a more detailed configuration of the cassette block 10 will be explained with reference to FIG. 4 and FIG. 5 as well as FIG. 1 and FIG. 2. FIG. 4 is an explanatory diagram illustrating a configuration of the cassette block 10 on the processing block 11 side. FIG. 5 is an explanatory diagram for describing the size of the cassette block 10.

The cassette block 10 has the first transfer mechanism 40 as stated above.

The first transfer mechanism 40 has, as illustrated in FIG. 4, a first guide member 42 and a second guide member 43 in addition to the fork 41.

The first guide member 42 guides a movement of the fork 41 in the vertical direction (Z-axis direction in the drawing). To elaborate, the first guide member 42 allows an elevating body 44 to be moved along it, for example. The elevating body 44 supports the fork 41 with a pivoting body 45 therebetween. The pivoting body 45 pivots on the elevating body 44. The fork 41 is moved forward and backward horizontally with respect to the pivoting body 45.

The second guide member 43 guides a movement of the first guide member 42 in the depth direction (X-axis direction in the drawing). Specifically, the second guide member 43 guides the movement of the first guide member 42 as follows. That is, as shown in FIG. 1 and FIG. 2, the second guide member 43 guides the movement of the first guide member 42 in the depth direction in an area of the first transfer space K1, in which the first transfer mechanism 40 is provided, adjacent to the cassette placement table 20 in the width direction (Y-axis direction in the drawing) when viewed from the top.

The cassette block 10 satisfies the following condition (A) in the width direction (Y-axis direction in the drawing).

(A) As shown in FIG. 5, a size (width) W1 of a gap h1 between the cassette placement table 20 and the transit block 30 is larger than a length (width) W2 of the first guide member 42 and smaller than a length (width) W3 of the fork 41.

Here, the “length of the fork 41” in the condition (A) refers to the size of the fork 41 in the width direction (Y-axis direction in the drawing) when it is moved in the depth direction (X-axis direction in the drawing).

As stated above, in the cassette block 10, the first transfer mechanism 40 is configured such that the wafer W supported by the fork 41 can pass through the transit block 30 in the depth direction (X-axis direction in the drawing) when viewed from the top. When the wafer W passes through the transit block 30 in this manner, the first guide member 42 can pass through the gap h1 since the cassette block 10 satisfies the aforementioned condition (A).

In addition, when the above-described condition (A) is satisfied, when the fork 41 moves in the depth direction (X-axis direction in the drawing), the first guide member 42 can pass through the gap h1, but the wafer W supported by the fork 41 cannot pass through the gap h1.

In addition, the first transfer mechanism 40 performs the delivery of the wafer W to/from the cassette placement table 20 from the processing block 11 side in the width direction (Y-axis direction in the drawing).

Meanwhile, the first transfer mechanism 40 performs the delivery of the wafer W to/from the transit block 30 (that is, the transfer of the wafer W to/from the transit block 30) only from the depth direction (X-axis direction in the drawing), without performing it from the width direction (Y-axis direction in the drawing). Specifically, the first transfer mechanism 40 performs the delivery of the wafer W to/from the transit block 30 only from the rear side (positive X-axis side in the drawing), and neither from the width direction (Y-axis direction in the drawing) nor from the front side (negative X-axis side in the drawing), as illustrated by a white dotted arrow in FIG. 1.

In addition, in the cassette block 10, the transit block 30 is provided in the first transfer space K1.

In the first transfer space K1, the transit block 30 is configured to deliver the wafer W to/from the second transfer mechanisms 70 of all the sub-blocks BL belonging to the processing block 11. As a specific example, the transit block 30 extends in the vertical direction (Z-axis direction in the drawing) and overlaps both the upper sub-block BL1 and the lower sub-block BL2 when viewed in the width direction (Y-axis direction in the drawing), as illustrated in FIG. 2.

The height of the upper end of the transit block 30 is approximately the same as the height of the ceiling surface of the housing 10a of the cassette block 10 that defines the first transfer space K1, for example. That is, the transit block 30 is designed so that there exists almost no gap between the transit block 30 and the ceiling surface of the housing 10a.

Further, a height of the lower end of the transit block 30 is set such that the wafer W can be delivered between the transit block 30 and the second transfer mechanism 70 of the lower sub-block BL2 as well. For example, the height of the lower end of the transit block 30 is approximately the same as the height of the lower end of the layer BL22.

As shown in FIG. 4, in the first transfer space K1 formed by the housing 10a, a portion on the front side (negative X-axis side in the drawing) of the transit block 30 is occupied by the storage section 50 for accommodating various electrical components. Specifically, as shown in FIG. 1 and FIG. 4, an upper portion of the first transfer space K1 on the processing block 11 side (positive Y-axis side in the drawing) in front of the transit block 30 is filled with the storage section 50. The storage section 50 is provided in approximately the same range as the transit block 30 in the vertical direction (Z-axis direction in the drawing). That is, the heights of the upper end and the lower end of the storage section 50 are approximately the same as those of the transit block 30.

The cassette block 10 is further equipped with the first blower 60. The first blower 60 supplies a clean gas into the first transfer space K1 from above. The first blower 60 includes a fan device 61 and a filter 62.

The fan device 61 sends the gas to the filter 62. As a specific example, the fan device 61 draws in a gas and sends the drawn gas to the filter 62.

The filter 62 purifies the gas sent from the fan device 61, that is, filters out particles in the gas, and discharges the purified gas (clean gas) towards the first transfer space K1 therebelow.

For example, the first blower 60 supplies the clean gas only to the rear side (positive X-axis side in the drawing) of the first transfer space K1 behind the transit block 30 that is not filled with the storage section 50.

Specifically, the filter 62 is provided only above the portion of the first transfer space K1 behind the transit block 30.

Further, evacuation from a bottom side of the cassette block 10 may be performed from both the front side and the rear side (both positive and negative X-axis sides in the drawing) so that the clean gas supplied from the first blower 60 into the first transfer space K1 flows under the storage section 50 through which the wafer W can pass. That is, exhaust ports (not shown) for evacuation from the first transfer space K1 may be provided on the front side and the rear side in a bottom portion of the cassette block 10.

In addition, the storage sections 51 and 52 for accommodating various electrical components may be further provided in the upper portion of the cassette block 10. Here, however, the heights of upper ends of the storage sections 51 and 52 need to be set to be equal to or less than the height of the upper end of the processing block 11. For example, the storage section 51 is provided above the filter 62, and the storage section 52 is provided above the transit block 30 and the storage section 50.

Also, the fan device 61 of the first blower 60 may be provided at a position higher than the first transfer space K1 to be located on the rear side (positive X-axis side in the drawing) of the first transfer space K1. In this case, a space under the fan device 61 may be configured as a storage section 53 for storing various electrical components. The storage section 53 may extend up to an area where it overlaps the cassette placement table 20 when viewed from the top.

### <Interface Block 12>

Now, a detailed configuration of the interface block 12 will be explained with reference to FIG. 6 in addition to FIG. 2. FIG. 6 is an explanatory diagram illustrating the configuration of the interface block 12.

As described above, the interface block 12 has the third transfer mechanism 120. For example, the third transfer mechanism 120 is configured such that the fork 121 moves only in a space on the front side (negative X-axis side in FIG. 6, etc.) of the transit block 110 and the fork 121 performs the delivery of the wafer W to/from the transit block 110 only from the front side.

Additionally, in the interface block 12, the transit block 110 is provided in a third transfer space K3 in which the third transfer mechanism 120 is provided.

In the third transfer space K3, the transit block 110 is configured to deliver the wafer W to/from the second transfer mechanisms 70 of all the sub-blocks BL included in the processing block 11. As a specific example, the transit block 110 extends in the vertical direction (Z-axis direction in the drawing) and overlaps both the upper sub-block BL1 and the lower sub-block BL2 when viewed in the width direction (Y-axis direction in the drawing), as shown in FIG. 2.

The transit block 110 is provided with a gap from a ceiling surface of a housing 12a of the interface block 12 that forms the third transfer space K3, as shown in FIG. 6, for example.

A storage section 140 for storing various electrical components is provided at an upper end of the third transfer space K3 on the rear side (positive X-axis side in the drawing). The storage section 140 is provided with a gap from the transit block 110.

Also, the depth (length in the X-axis direction in the drawing) of the housing 12a forming the third transfer space K3 is smaller than the depth of the processing block 11. For this reason, although the edges of the housing 12a and the processing block 11 on the front side (negative X-axis side in the drawing) are substantially aligned, their edges on the rear side (positive X-axis side in the drawing) are not aligned, and the edge of the processing block 11 is located further back.

Furthermore, the interface block 12 is equipped with the third blower 130.

The third blower 130 supplies a clean gas into the third transfer space K3 from above. The third blower 130 includes a fan device 131 and a filter 132.

The fan device 131 sends the gas to the filter 132. As a specific example, the fan device 131 draws in the gas and sends the drawn gas to the filter 132 via a duct 133.

The filter 132 purifies the gas sent from the fan device 131, that is, filters particles in the gas, and discharges the purified gas (clean gas) toward the third transfer space K3 therebelow.

The third blower 130 supplies the clean gas to the following portions of the third transfer space K3, for example:
a space on the front side (negative Y-axis side in the drawing) of the transit block 110 through which the wafer W can pass;
a space overlapping the transit block 110 when viewed from the top; and
a space between the transit block 110 and the storage section 140

Specifically, the filter 132 is disposed to range from the front edge (negative X-axis side in the drawing) of the housing 12a up to the space between the transit block 110 and the storage section 140.

Also, the fan device 131 of the third blower 130 may be provided on the rear side (positive X-axis side in the drawing) of the housing 12a. In this case, however, the fan device 131 is disposed such that its rear edge is not located further back than the rear edge the processing block 11.

As described above, the fan device 101 of the second blower 100 used in the processing block 11 may be stacked on top of the interface block 12. Specifically, the fan device 101 may be stacked on top of the filter 132. However, the height of the upper end of the fan device 101 is set to be equal to or less than the height of the upper end of the processing block 11. By providing the fan device 101 in this manner, an increase of the overall height of the coating and developing apparatus 1 can be suppressed.

In addition, storage sections 141 and 142 may be provided above a portion of the interface block 12 on the front side (negative X-axis side in the drawing) of the fan device 101 and above a portion of the interface block 12 on the rear side (positive X-axis side in the drawing) thereof, respectively. However, the heights of upper ends of the storage sections 141 and 142 are set to be equal to or less than the height of the upper end of the processing block 11. The storage sections 141 and 142 accommodate, for example, items that are conventionally mounted above the processing block 11 (for example, electrical components for the resist film forming module COT and/or electrical equipment for the second transfer mechanism 70). By providing the storage sections 141 and 142 in this way, the increase of the overall height of the coating and developing apparatus 1 can be suppressed.

### Example of Processing by Coating and Developing Apparatus 1

Now, an example of a processing by the coating and developing apparatus 1 will be explained. The following individual processes are performed under the control of the controller 200 based on the program stored in the program storage (not shown).

### (Process S1)

First, the wafer W is carried into the transit block 30 of the coating and developing apparatus 1.

To elaborate, with the elevating plate (not shown) of the placement plate 21 on the front side (negative X-axis side in FIG. 4, etc.) of the cassette placement table 20 moved to the aforementioned second position, the wafer W on the elevating plate is delivered to the fork 41 of the first transfer mechanism 40.

Then, the wafer W supported by the fork 41 is moved toward the rear side (positive X-axis side in FIG. 4, etc.) when viewed from the top to pass through the transit block 30.

Specifically, the first guide member 42 is moved toward the rear side along the depth direction, and the wafer W supported by the fork 41 passes through a space under the transit block 30 and is moved further back than the transit block 30.

In one exemplary embodiment, the height of the wafer W is approximately the same when it is delivered from the elevating plate of the placement plate 21 onto the fork 41 and when it passes through the transit block 30 when viewed from the top.

Thereafter, the wafer W supported by the fork 41 is delivered from the rear side (positive X-axis side in FIG. 4, etc.) of the transit block 30 to the transit block 30.

Specifically, the fork 41 is advanced into the transit module 31 corresponding the lower sub-block BL2 of the transit block 30 from the rear thereof, and the wafer W is delivered from the fork 41 into the transit module 31.

### (Process S2)

Next, a resist film coating process is performed on the wafer W, so that a resist film is formed on the wafer W.

As a specific example, the wafer W is transferred by the second transfer mechanism 70 from the transit module 31 corresponding to the lower sub-block BL2 in the transit block 30 to the resist film forming module COT in the lower sub-block BL2. Then, a resist liquid is spin-coated on a front surface of the wafer W, so that the resist film is formed so as to cover the front surface of the wafer W.

### (Process S3)

Subsequently, the wafer W is subjected to a pre-applied bake (PAB) process.

Specifically, the wafer W is transferred by the second transfer mechanism 70 into the heat treatment module HT for PAB, where the wafer W is subjected to the PAB processing. Thereafter, the wafer W is transferred into the transit module 111 corresponding to the lower sub-block BL2 in the transit block 110 of the interface block 12.

### (Process S4)

Next, the wafer W is subjected to an exposure process.

As a specific example, the wafer W is transferred by the third transfer mechanism 120 from the transit module 111 corresponding to the lower sub-block BL2 in the transit block 110 into the exposure apparatus, where the resist film on the wafer W is exposed into a predetermined pattern. Thereafter, the wafer W is transferred by the third transfer mechanism 120 into the transit module 111 corresponding to the upper sub-block BL1 in the transit block 110.

### (Process S5)

Then, the wafer W is subjected to a post exposure bake (PEB) process.

As a specific example, the wafer W is transferred by the second transfer mechanism 70 from the transit module 111 corresponding to the upper sub-block BL1 in the transit block 110 to the heat treatment module HT for PEB in the upper sub-block BL1, where the wafer W is subjected to the PEB process.

### (Process S6)

Subsequently, the wafer W is subjected to a developing process.

As a specific example, the wafer W is transferred by the second transfer mechanism 70 into the developing module DEV, where the wafer W is subjected to the developing process with a developing liquid.

### (Process S7)

Thereafter, the wafer W is subjected to a post bake process.

As a specific example, the wafer W is transferred by the second transfer mechanism 70 to the heat treatment module HT for post-baking, and the post-baking process is performed on the wafer W. Thereafter, the wafer W is transferred by the second transfer mechanism 70 to the transit module 31 corresponding to the upper sub-block BL1 in the transit block 30 of the cassette block 10.

### (Process S8)

Then, the wafer W is carried out from the coating and developing apparatus 1.

Specifically, the wafer W is returned back onto the elevating plate (not shown) of the placement plate 21 on the front side (negative X-axis side in FIG. 4, etc.) of the cassette placement table 20, which is located at the aforementioned second position, in the reverse order as described in the process S1.

In this way, the processing by the coating and developing apparatus 1 is completed.

### Main Effects of Present Exemplary Embodiment

As described above, in the coating and developing apparatus 1, the cassette block 10 has the transit block 30 in which the transfer modules 31 configured to transfer the wafer W between the cassette block 10 and the processing block 11 are stacked. Therefore, as compared to when the processing block 11 has the transit block 30, it is possible to include more processing modules in the processing block 11 for the sake of achieving the high throughput, without needing to change the footprint of the processing block 11.

Also, in the coating and developing apparatus 1, the cassette block 10 has the first transfer mechanism 40 configured to transfer the wafer W between the cassette placement table 20 and the transit block 30. The first transfer mechanism 40 has the fork 41, and is configured such that the wafer W supported by the fork 41 can pass through the transit block 30 in the depth direction (X-axis direction in FIG. 4, etc.) when viewed from the top. Therefore, as compared to a case where it is impossible for the wafer W to pass through in this way, that is, as compared to a case where the wafer W supported by the fork 41 passes through an area that does not overlap the transit block 30 when viewed from the top when the wafer W is moved in the depth direction, the following effects may be achieved. That is, it is possible to suppress the increase in the footprint of the cassette block 10 that might be caused by providing the transit block 30 in the cassette block 10.

Therefore, according to the present exemplary embodiment, it is possible to suppress the enlargement of the apparatus that might accompany the high throughput. That is, according to the present exemplary embodiment, it is possible to improve the productivity by providing more processing modules without significantly increasing the size of the apparatus.

Further, in the present exemplary embodiment, the first transfer mechanism 40 performs the delivery of the wafer W to/from the transit block 30 only from the depth direction (X-axis direction in FIG. 4, etc.), and not from the width direction (Y-axis direction in FIG. 4, etc.). Therefore, in the width direction, the size of the space that does not overlap with the cassette placement table 20 when viewed from the top can be minimized. Specifically, in the width direction, the gap h1 between the cassette placement table 20 and the transit block 30 can be minimized. Therefore, according to the present exemplary embodiment, it is possible to suppress the enlargement of the apparatus.

Furthermore, in the present exemplary embodiment, the first transfer mechanism 40 performs the delivery of the wafer W to/from the transit block 30 only from the rear side (positive X-axis side in FIG. 4, etc.), and neither from the width direction (Y-axis direction in FIG. 4, etc.) nor from the front side (negative X-axis side in FIG. 4, etc.). In addition, the first blower 60 supplies the clean gas only to the rear of the transit block 30 that is not filled with the storage section 50 in the first transfer space K1. Therefore, it is possible to suppress the clean gas from staying in the first transfer space K1, while suppressing size-up of the first blower 60.

In addition, in the present exemplary embodiment, the fan device 101 of the second blower 100 for the processing block 11 is provided on the interface block 12 whose upper end is lower than the processing block 11. Therefore, the height of the coating and developing apparatus 1 can be reduced as compared to a case where the fan device 101 is provided on the processing block 11.

### Specific Example of Height of Transit Block and Modification Example

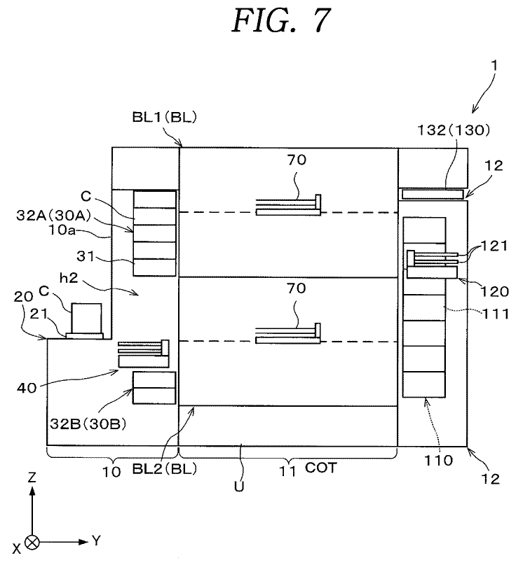

FIG. 7 is an explanatory diagram illustrating a modification example of the transit block included in the cassette block 10.

In the above-described exemplary embodiment, the transit block 30 of the cassette block 10 extends vertically and overlaps the upper sub-block BL1 and the lower sub-block BL2 when viewed in the width direction (Y-axis direction in FIG. 2, etc.). That is, the transit block 30 has a block 32 corresponding to the upper sub-block BL1 and a block 33 corresponding to the lower sub-block BL2, and these blocks 32 and 33 are connected vertically.

Alternatively, as in a transit block 30A of FIG. 7, a gap h2 may be provided between a block 32A corresponding to the upper sub-block BL1 and a block 32B corresponding to the lower sub-block BL2. In this case, the wafer W supported by the fork 41 of the first transfer mechanism 40 passes through the gap h2 when it passes through the transit block 30 in the depth direction when viewed from the top.

### Specific Example of Liquid Processing Layer in Processing Block

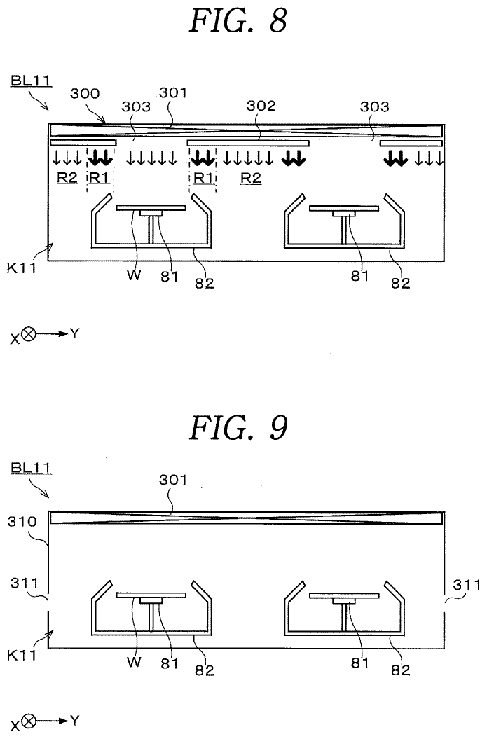

FIG. 8 is an explanatory diagram illustrating a specific example of the upper layer BL11 of the upper sub-block BL1 in the processing block 11. The configuration of each of the lower layer BL12 of the upper sub-block BL1 and the upper and lower layers BL21 and BL22 of the lower sub-block BL2 is the same as the configuration of the upper layer BL11 of the upper sub-block BL1.

The upper layer BL11 has a gas flow forming device 300, as shown in FIG. 8. The gas flow forming device 300 is configured to generate a gas flow heading from above the cup 82 to below the cup 82 in the processing space K11 in which the spin chuck 81 and the cup 82 are provided.

The gas flow forming device 300 includes a fan filter unit (FFU) 301 as a fourth blower configured to supply a clean gas into the processing space K11 from above.

The gas flow forming device 300 has a rectifying plate 302 in addition to the FFU 301. The rectifying plate 302 is provided between the cup 82 and the FFU 301, and forms a downward flow from a gas discharged from the FFU 301.

The rectifying plate 302 has an opening 303 for each spin chuck 81, that is, for each cup 82. Each opening 303 is provided at a position facing the corresponding spin chuck 81, and forms a gas flow toward the wafer W held by the corresponding spin chuck 81.

In addition, the rectifying plate 302 forms a stronger gas flow in an area R1 surrounding an outer periphery of the corresponding opening 303 than in an outer area R2, when viewed from the top. Hereinafter, the areas R1 and R2 will sometimes be referred to as a strong flow forming area R1 and a weak flow forming area R2, respectively.

The rectifying plate 302 is provided with a discharge hole (not shown) through which the gas from the FFU 301 is discharged downwards. The discharge hole is plural in number, and these discharges holes are formed in both areas of the rectifying plate 302 corresponding to the strong flow forming area R1 and the weak flow forming area R2, respectively. A first opening ratio, which is the ratio of the discharge holes in the area of the rectifying plate 302 facing the strong flow forming area R1, is lower than a second opening ratio, which is the ratio of the discharge holes in the area facing the weak flow forming area R2. As a result, the flow velocity of the gas flow formed by the gas discharged from the discharge holes in the area facing the strong flow forming area R1 becomes higher than the flow velocity of the gas flow formed by the gas discharged from the discharge holes in the area facing the weak flow forming area R2. That is, a stronger gas flow may be formed in the strong flow forming area R1 than in the weak flow forming area R2.

The strong gas flow formed in the strong flow forming area R1 functions as an air curtain. Therefore, it is possible to suppress the influence of the external factor existing in the weak flow forming area R2 from reaching a region above the cup 82 inside the strong flow forming area R1. Specifically, it is possible to suppress particles in the weak flow forming area R2 from being included in the gas flow heading downwards from the opening 303, that is, the gas flow heading toward the wafer W.

As shown in FIG. 9, the upper layer BL11 may be provided with an opening 311 in a sidewall 310 covering the side of the processing space K11. The opening 311 allows the processing space K11 to communicate with an adjacent space (for example, the first transfer space K1 or the third transfer space K3). By providing the opening 311, the gas inside the processing space K11 can be released to the adjacent space.

The opening 311 is provided at, for example, a lower portion of the sidewall 310, specifically, at a portion of the sidewall 310 below an upper end of the cup 82. With this configuration, when the gas in the adjacent space returns back into the processing space K11 through the opening 311, particles contained in that gas can be suppressed from reaching the inside of the cup 82.

Alternatively, the opening 311 may be provided at an upper portion of the sidewall 310. Specifically, it may be provided at a portion of the sidewall 310 above the upper end of the cup 82. This allows the gas in the processing space K11 to be released to the adjacent space through the opening 311 when the pressure in the processing space K11 suddenly increases or when the gas flow in the processing space K11 gets suddenly stronger.

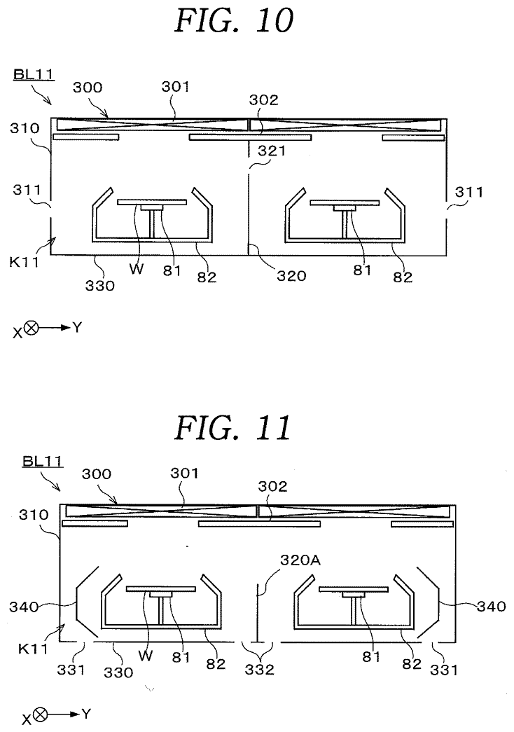

As shown in FIG. 10, a partition wall 320 may be provided to separate the cups 82 in the width direction (Y-axis direction in the drawing). This makes it possible to suppress the following gas flows from affecting each other in a portion of the processing space K11 where one cup 82 is provided and a portion of the processing space K11 where the other cup 82 is provided:
a gas flow formed by the gas flow forming device 300, that is, a downflow, and
an exhaust gas from the outside of the cup 82.

Further, the height of the partition wall 320 is equal to the height of the processing space K11 (when the rectifying plate 302 is provided, height from a bottom wall 330 of the layer BL11 to the rectifying plate 302), for example. In this case, the partition 320 is provided with an opening 321 through which the nozzle 83 passes when the nozzle 83 is moved in the width direction (Y-axis direction in the drawing).

As illustrated in FIG. 11, a rectifying member 340 may be provided between the cup 82 and a sidewall 310. The rectifying member 340 guides the gas from the FFU 301 toward an exhaust opening 331 provided outside the cup 82 in a lower portion of the processing space K11.

The exhaust opening 331 is provided for each cup 82, for example, between the corresponding cup 82 and the sidewall 310. At least a lower end of the rectifying member 340 may be located between the cup 82 and the exhaust opening 331, and another portion of the rectifying member 340 may be located between the exhaust opening 331 and the sidewall 310.

Also, the height of an upper and of a partition wall 320A separating the cups 82 may be lower than the height of the upper end of the cup 82. In this case, for each cup 82, an exhaust opening 332 through which the processing space K11 is evacuated from the outside of the cup 82 may be provided between the partition wall 320A and the corresponding cup 82. This makes it easy to individually control the pressure and the gas flow in the portion of the processing space K11 where the one cup 82 is provided and the portion of the processing space K11 where the other cup 82 is provided.

Further, in the example shown in the drawings, the exhaust openings 331 and 332 are provided at the bottom wall 330. However, the exhaust openings 331 and 332 may be provided at a portion other than the bottom wall 330 that is located outside the cup 82 and is lower than the upper end of the cup 82.

### First Modification Example of Processing Block

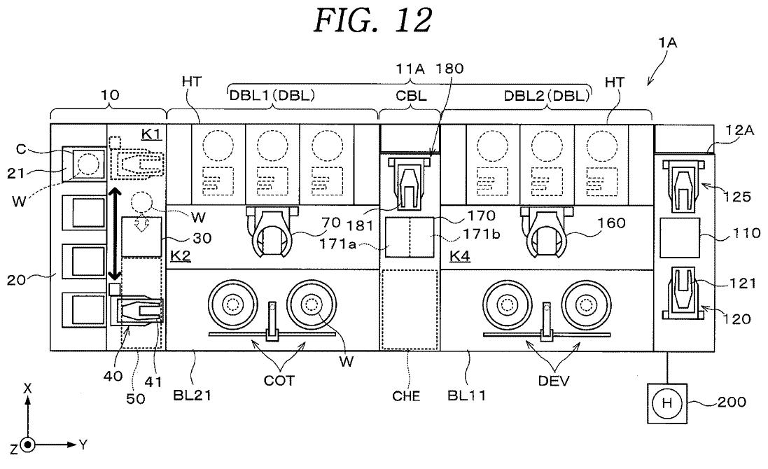

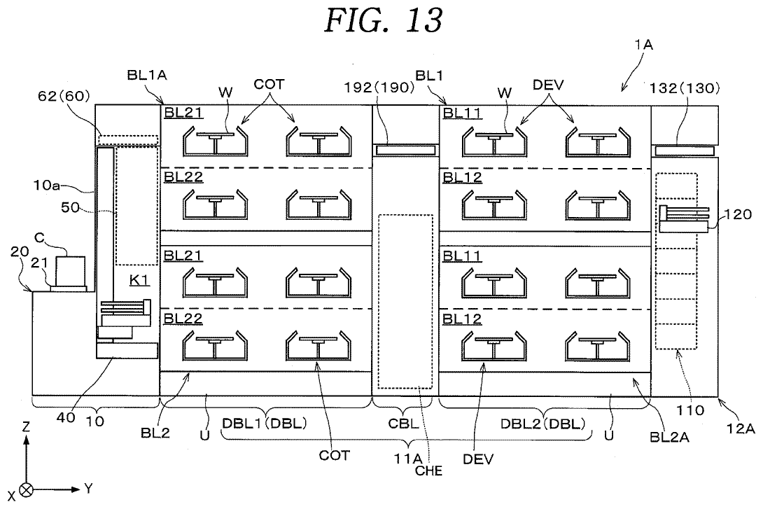

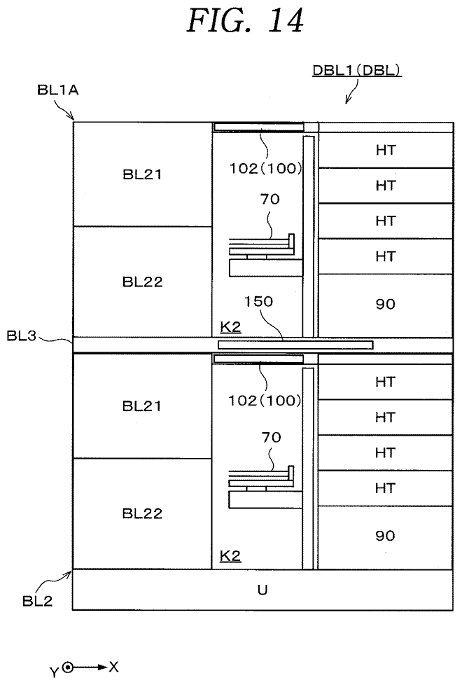

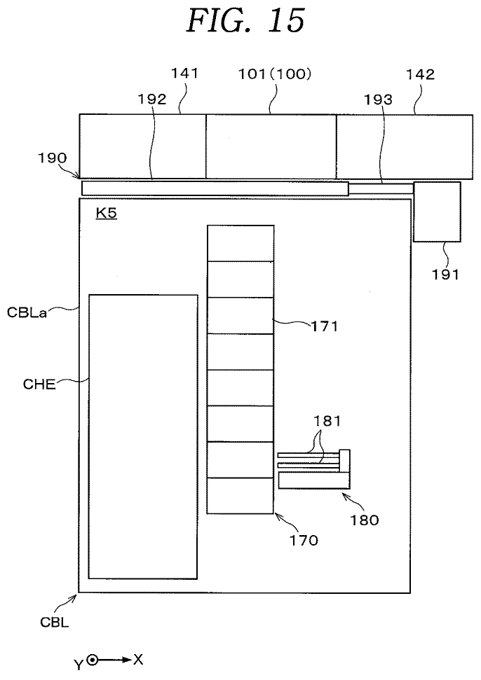

FIG. 12 is an explanatory diagram showing a schematic configuration of a first modification example of the processing block. FIG. 13 is an explanatory diagram illustrating a schematic configuration of a front side of the processing block of FIG. 12. FIG. 14 is an explanatory diagram illustrating a schematic configuration of a division block to be described later. FIG. 15 is an explanatory diagram illustrating a configuration of an intermediate block to be described later.

A coating and developing apparatus 1A of FIG. 12 and FIG. 13 is different from the coating and developing apparatus 1 shown in FIG. 1, etc. in the configuration of a processing block. Specifically, a processing block 11A of the coating and developing apparatus 1A is divided into a plurality of division blocks DBL in the width direction (Y-axis direction in the drawing). In the example of FIG. 12, the processing block 11A is divided into two division blocks DBL, and an intermediate block CBL is provided between the two neighboring division blocks DBL. In the following, the division block DBL on the negative width direction (left side in the drawing) will be referred to as a left division block DBL1, and the division block DBL on the positive width direction (right side in the drawing) will be referred to as a right division block DBL2.

Each of the division blocks DBL has the same configuration as the processing block 11 described above by using FIG. 1, etc. Below, the division blocks DBL and the intermediate block CBL will be described. Description of the division blocks DBL, however, will mainly focus on distinctive features from the processing block 11.

In the left division block DBL1 of the two division blocks DBL, an upper sub-block BL1A and the lower sub-block BL2 are stacked in this order from above, and a shuttle layer BL3 is provided between the upper sub-block BL1A and the lower sub-block BL2, as shown in FIG. 14.

Each of the upper sub-block BL1A and the lower sub-block BL2 of the left division block DBL1 is provided with the second transfer mechanism 70, the same as the upper sub-block BL1 of the processing block 11 described above. However, the second transfer mechanism 70 provided in the left division block DBL1 transfers the wafer W not only between the transit block 30 and the processing module within the left division block DBL1 and between the processing modules within the left division block DBL1, but also between the processing module of the left division block DBL1 and a transit block 170 (to be described later) of the intermediate block CBL.

Further, in the left division block DBL1, a portion of the upper sub-block BL1A on the front side (negative X-axis side in the drawing) of the second transfer space K2 is different from that of the processing block 11 described above, and is divided into an upper layer BL21 and a lower layer BL22 in which the resist film forming modules COT are provided, the same as in the lower sub-block BL2. That is, in the left division block DBL1, the layers in which the resist film forming modules COT are provided are stacked in four levels.

The other configurations of the upper sub-block BL1A and the lower sub-block BL2 of the left division block DBL1 are the same as those of the upper sub-block BL1 and the lower sub-block BL2 of the above-described processing block 11.

The shuttle layer BL3 is provided with a shuttle transfer mechanism 150. The shuttle transfer mechanism 150 is configured to transfer the wafer W only linearly in the width direction (Y-axis direction in the drawing). In the present example, the shuttle transfer mechanism 150 transfers the wafer W only linearly in the width direction (Y-axis direction in the drawing) between the transit block 30 of the cassette block 10 and the transit block 170 of the intermediate block BLC. That is, the shuttle transfer mechanism 150 transfers the wafer W linearly in the width direction between the transit blocks. Therefore, the shuttle transfer mechanism 150 does not transfer the wafer W to the processing module of the processing block 11.

When viewed from the top, the linear transfer path of the wafer W by the shuttle transfer mechanism 150 does not overlap with the processing modules of the left division block DBL1, but overlaps with the second transfer space K2 in which the second transfer mechanism 70 is provided.

Meanwhile, in the right division block DBL2, the upper sub-block BL1 and the lower sub-block BL2A are stacked in this order from the top, as illustrated in FIG. 13. Also, although not shown, in the right division block DBL2, the shuttle layer BL3 is provided between the upper sub-block BL1 and the lower sub-block BL2A, the same as in the left division block DBL1.

A transfer mechanism 160 (see FIG. 12) is provided in each of the upper sub-block BL1 and the lower sub-block BL2A of the right division block DBL2. Like the second transfer mechanism 70 provided in the left division block DBL1, the transfer mechanism 160 is configured to transfer the wafer W to the processing module within the right division block DBL2. Specifically, the transfer mechanism 160 transfers the wafer W between the transit block 170 of the intermediate block CBL and the processing module within the right division block DBL2, between the processing modules within the right division block DBL2, and between the processing module within the right division block DBL2 and the transit block 110 of the interface block 12A described below.

Further, in the right division block DBL2, a portion of the lower sub-block BL2A on the front side (negative X-axis side in the drawing) of the second transfer space K2 is different from that of the processing block 11 described above, and is divided into the upper layer BL11 and the lower layer BL12 in which the developing modules DEV are provided, the same as in the upper sub-block BL1. That is, in the right division block DBL2, the layers in which the developing modules DEV are provided are stacked in four levels.

The other configurations of the upper sub-block BL1 and the lower sub-block BL2A of the right division block DBL2 are the same as those of the upper sub-block BL1 and the lower sub-block BL2 of the aforementioned processing block 11.

The shuttle layer BL3 of the right division block DBL2 is also provided with the shuttle transfer mechanism 150. However, the shuttle transfer mechanism 150 of the right division block DBL2 transfers the wafer W only linearly in the width direction (Y-axis direction in the drawing) between the transit block 170 of the intermediate block BLC and the transit block 110 of the interface block 12A.

In the shuttle layer BL3 of the right division block DBL2, the shuttle transfer mechanism 150 performs the linear transfer of the wafer W so that, when viewed from the top, the wafer W does not pass over an area overlapping the processing module of the right division block DBL2 but passes over a transfer space K4 in which the transfer mechanism 160 is provided.

As shown in FIG. 12, the intermediate block CBL is provided between the two division blocks DBL arranged in the width direction, and is configured to relay the wafer W between them.

As depicted in FIG. 15, the intermediate block CBL has the transit block 170. The transit block 170 is a stack of transit modules 171 for delivering the wafer W. In the intermediate block CBL, the transit block 170 is provided at a position interposed between the second transfer space K2 of the left division block DBL1 and the transfer space K4 of the right division block DBL2.

Among the transit modules 171 included in the transit block 170, those accessible by the shuttle transfer mechanism 150 may be provided separately for the shuttle transfer mechanism 150 of the left division block DBL1 and for the shuttle transfer mechanism 150 of the right division block DBL2. This suppresses a transfer by one shuttle transfer mechanism 150 from being hindered by a transfer by the other shuttle transfer mechanism 150.

When provided separately in this way, a transit module 171a for the shuttle transfer mechanism 150 of the left division block DBL1 and a transit module 171b for the shuttle transfer mechanism 150 of the right division block DBL2 may be arranged in the width direction (Y-axis direction in the drawing) on the same level, as illustrated in FIG. 12. Thus, the shuttle layer BL3 can be provided at the same height in the left division block DBL1 and the right division block DBL2, which suppresses the increase of the height of the apparatus when the shuttle layer BL3 is provided.

Likewise, in the transit block 170, for any level other than the level where the transit module 171 for the shuttle transfer mechanism 150 is provided, the transit modules 171 may be provided separately for the left division block DBL1 and the right division block DBL2, and may be arranged in the width direction (Y-axis direction in the drawing).

Furthermore, the intermediate block CBL has a transfer mechanism 180 configured to transfer the wafer W between the transit module 171 for the shuttle transfer mechanism 150 of the transit block 170 and another transit module 171. The transfer mechanism 180 has a fork 181 for supporting the wafer W. The fork 181 is configured to be movable in the vertical direction (Z-axis direction in the drawing), around a vertical axis, in the depth direction (X-axis direction in the drawing), and in the width direction (Y-axis direction in the drawing).

In the intermediate block CBL, the aforementioned transit block 170 is provided in a transfer space K5 in which the transfer mechanism 180 is provided. The transit block 170 is provided with a gap from a ceiling surface of a housing CBLa of the intermediate block CBL that forms the transfer space K5.

In a front side (negative X-axis side in the drawing) of the transfer space K5, there is provided a chemical section CHE in which a bottle that stores the coating liquid (specifically, the resist liquid) for use in the resist film forming module COT, a pump configured to force-feed the coating liquid to the resist film forming module COT, and so forth are accommodated.

Further, the depth (length in the X-axis direction in the drawing) of the housing CBLa forming the transfer space K5 is smaller than the depth of the division block DBL. Thus, although the edges of the housing CBLa and the division block DBL on the front side (negative X-axis side in the drawing) are substantially aligned, their edges on the rear side (positive X-axis side in the drawing) are not aligned, and the edge of the division block DBL is located further back.

Furthermore, the intermediate block CBL is provided with a blower 190.

The blower 190 is configured to supply a clean gas into the transfer space K5 from above. The blower 190 includes a fan device 191 and a filter 192.

The fan device 191 sends the gas to the filter 192. As a specific example, the fan device 191 takes in the gas and sends the taken gas to the filter 192 via a duct 193.

The filter 192 purifies the gas sent from the fan device 191, that is, filters particles in the gas, and ejects the purified gas (clean gas) toward the transfer space K5 below.

The blower 190 supplies the clean gas to the following portions of the transfer space K5, for example:
a space on the rear side (positive X-axis side in the drawing) of the transit block 170 through which the wafer W can pass; and
a space overlapping the transit block 170 when viewed from the top.

Also, the fan device 191 of the blower 190 may be provided on the rear side (positive X-axis side in the drawing) of the housing CBLa. In this case, however, the fan device 191 is disposed such that its rear edge is not located further back than the rear edge the division block DBL.

The fan device 101 of the second blower 100 used in the left division block DBL1 may be stacked on top of the intermediate block CBL. Specifically, the fan device 101 may be stacked on top of the filter 192. Here, however, the height of the upper end of the fan device 101 is set to be equal to or lower than the height of an upper end of the division block DBL. By providing the fan device 101 in this manner, an increase of the overall height of the coating and developing apparatus 1A can be suppressed.

In addition, the aforementioned storage sections 141 and 142 may be provided above a portion of the intermediate block CBL on the front side (negative X-axis side in the drawing) of the fan device 101 and a portion on the rear side (positive X-axis side in the drawing) of the fan device 101, respectively. Here, however, the heights of the upper ends of the storage sections 141 and 142 are set to be equal to or less than the height of the upper end of the division block DBL.

Furthermore, the coating and developing apparatus 1A of FIG. 12 differs from the coating and developing apparatus 1 shown in FIG. 1, etc. in the configuration of the interface block. Specifically, the interface block 12A of the coating and developing apparatus 1A is provided with a transfer mechanism 125 configured to transfer the wafer W between the transit module 171 accessed by the shuttle transfer mechanism 150 in the transit block 110 and another transit module 171. This transfer mechanism 125 is provided on the rear side (positive X-axis side in the drawing) of the transit block 110, for example.

The other configurations of the interface block 12A are the same as those of the interface block 12.

In the coating and developing apparatus 1A, the wafer W is supported in the following order, for example, to be subjected to the resist film coating process, the exposure process, and so forth. In the following description, among the transit modules, those accessed by any of the shuttle transfer mechanisms are referred to as shuttle transit modules, and those that are not accessed by any of the shuttle transfer mechanisms are referred to as a non-shuttle transit module.

First transfer mechanism 40→non-shuttle transit module 31 in the transit block 30→second transfer mechanism 70→resist film forming module COT in the left division block DBL1→second transfer mechanism 70→heat treatment module HT for PAB in the left division block DBL1→second transfer mechanism 70→non-shuttle transit module 171 in the intermediate block CBL→transfer mechanism 180→transit module 171b in the intermediate block CBL→shuttle transfer mechanism 150 in the right division block DBL2→shuttle transit module 111 in the interface block 12A→transfer mechanism 125→non-shuttle transit module 111 in the transit block 110→third transfer mechanism 120→exposure apparatus

Also, the wafer W is supported in the following order, for example, to be subjected to the PEB process, the developing process, and so forth.

Exposure apparatus→third transfer mechanism 120→non-shuttle transit module 111 of the interface block 12A→transfer mechanism 160→heat treatment module HT for PEB in the right division block DBL2→transfer mechanism 160→developing module DEV in the right division block DBL2→transfer mechanism 160→heat treatment module HT for post-bake processing in the right division block DBL2→transfer mechanism 160→non-shuttle transit module 171 in the intermediate block CBL→transfer mechanism 180→transit module 171a in the intermediate block CBL→shuttle transfer mechanism 150 in the left division block DBL1→shuttle transit module 31 in the transit block 30→first transfer mechanism 40

By using the above-described processing block 11A, it is possible to increase the number of processing modules provided in the processing block 11A.

### Second Modification Example of Processing Block

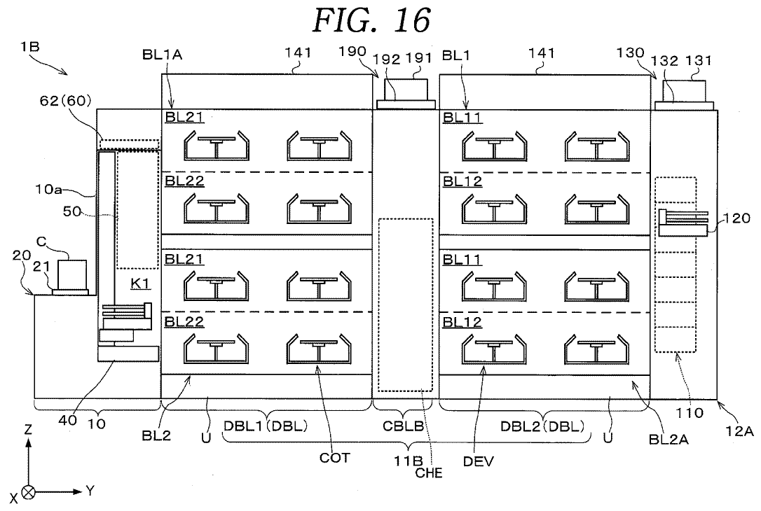

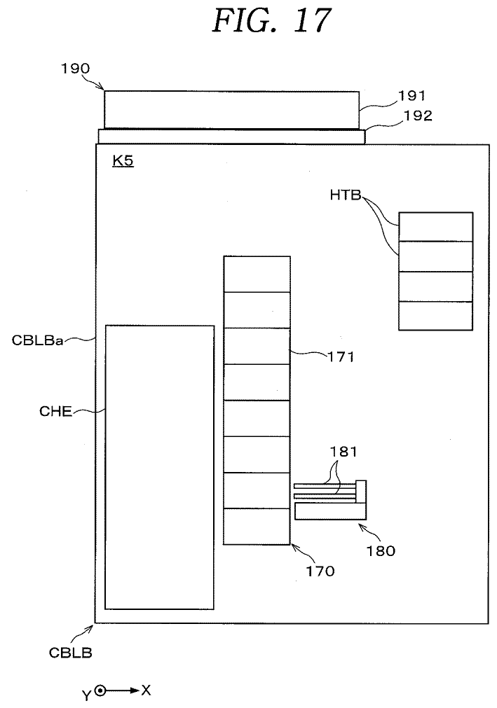

FIG. 16 is an explanatory diagram illustrating a configuration of a second modification example of the processing block. Specifically, FIG. 17 is an explanatory diagram illustrating a configuration of an intermediate block CBLB.

In a coating and developing apparatus 1B of FIG. 16, a processing block 11B is divided in the width direction (Y-axis direction in the drawing), the same as in the coating and developing apparatus 1A shown in FIG. 12, etc. Unlike in the coating and developing apparatus 1A, however, the storage section 141 is provided above each of the left division block DBL1 and the right division block DBL2 in the coating and developing apparatus 1B. Also, as depicted in FIG. 17, neither the storage section 141 nor the storage section 142 is provided above the intermediate block CBLB.

Therefore, the height of an upper end of the intermediate block CBLB can be raised to the height of the upper end of the division block DBL. By raising the height of the intermediate block CBLB in this way, an operator is enabled to easily access the uppermost level of the division block DBL via the intermediate block CBLB for maintenance of the processing modules in the uppermost level of the division block DBL. That is, maintenance is facilitated.

In addition, even if the height of the upper end of the intermediate block CBLB is increased as stated above, the upper end of the intermediate block CBLB is apart from the upper end of the storage section 141 in the division block DBL, so that both the fan device 191 and the filter 192 of the blower 190 can be provided above the intermediate block CBLB.

Furthermore, if the fan device 191 is provided above the intermediate block CBLB, rather than on the rear side of the intermediate block CBLB (housing CBLBa), a rear edge (the edge on the positive X-axis side in the drawing) of the housing CBLBa may be enlarged to a rear edge of the division block DBL. As a result, a processing module can be provided in a space of the intermediate block CBLB on the rear side of the transfer mechanism 180. As a specific example, a processing module smaller than the heat treatment module HT provided in the division block DBL is disposed in the space of the intermediate block CBLB on the rear side of the transfer mechanism 180. More specifically, when the heat treatment module HT has both a hot plate and a cooling plate, a heat treatment module HTB only having a hot plate is provided in the space of the intermediate block CBLB on the rear side of the transfer mechanism 180.

In addition, by increasing the height of the upper end of the intermediate block CBLB as stated above, a module (for example, an imaging module for inspection) whose dimension in the depth direction (X-axis direction in the drawing) is equal to that of the heat treatment module HT, etc., can be provided in an area of the intermediate bock CBLB on the front side (negative X-axis side in the drawing) where no chemical section CHE exists.

In addition, when the storage sections 141 and 142 are not provided above the interface block 12A, the height of an upper end of the interface block 12A may be increased, and both the fan device 131 and the filter 132 of the third blower 130 may be provided above the interface block 12A.

### Third Modification Example of Processing Block

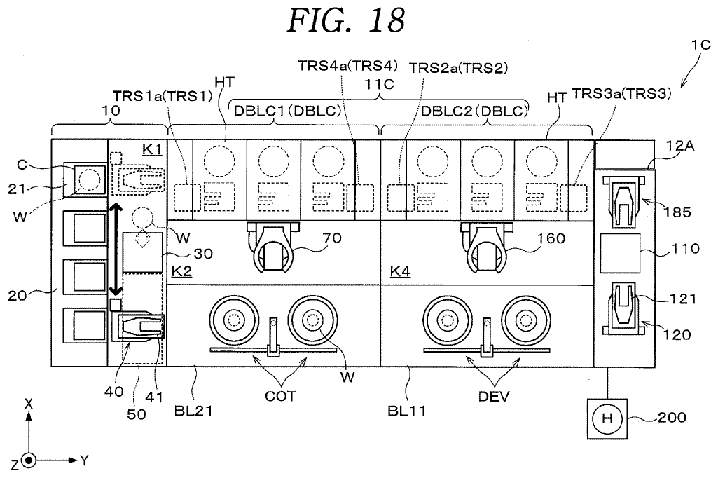

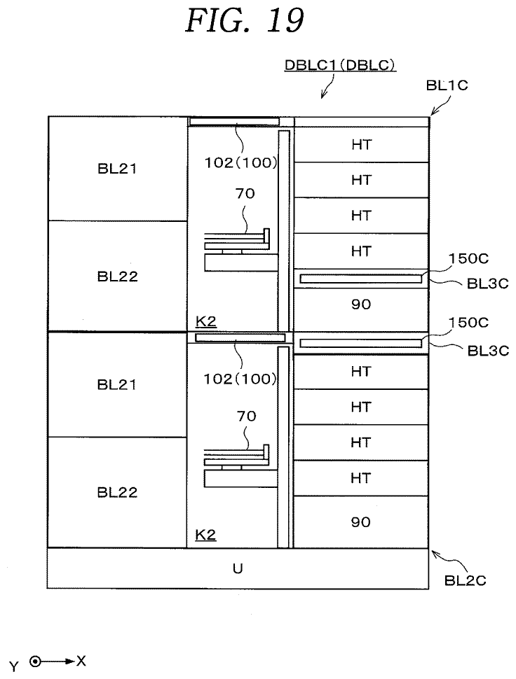

FIG. 18 is an explanatory diagram illustrating a schematic configuration of a third modification example of the processing block. FIG. 19 is an explanatory diagram showing a configuration of a division block DBLC.

In a coating and developing apparatus 1C of FIG. 18, a processing block 11C is divided into a plurality of division blocks DBLC in the width direction (Y-axis direction in the drawing), the same as in the coating and developing apparatus 1A shown in FIG. 12, etc. Unlike in the coating and developing apparatus 1A, however, no intermediate block is provided between the neighboring division blocks DBLC, and the plurality of division blocks DBLC constituting the processing block 11C are arranged side by side in the width direction (Y-axis direction in the drawing). In the example of FIG. 18, the processing block 11C is divided into two division blocks DBLC, and no intermediate block is provided between the two adjacent division blocks DBLC. In the following description, the division block DBL on the negative side (left side in the drawing) in the width direction will sometimes be referred to as a left division block DBLC1, and the division block DBLC on the positive side (right side in the drawing) in the width direction will sometimes be referred to as a right division block DBLC2.

Of the two division blocks DBLC, in the left division block DBLC1, an upper sub-block BL1C and a lower sub-block BL2C are stacked in this order from the top, and a shuttle layer BL3C is provided in each of the upper sub-block BL1C and the lower sub-block BL2C, as shown in FIG. 19.

Each of the upper sub-block BL1C and the lower sub-block BL2C of the left division block DBLC1 is provided with the second transfer mechanism 70, the same as the upper sub-block BL1 of the processing block 11 described above. However, the second transfer mechanism 70 provided in the left division block DBLC1 is configured to transfer the wafer W between processing modules within the left division block DBLC1 and a transit module TRS4 to be described later as well as between the transit block 30 and the processing modules within the left division block DBLC1 and between the processing modules within the left division block DBLC1 themselves.

In addition, in the left division block DBLC1, a space on the front side (negative X-axis side in the drawing) of the second transfer space K2 in each of the upper sub-block BL1C and the lower sub-block BL2C is divided into the upper layer BL21 and the lower layer BL22 in which the resist film forming modules COT are provided, the same as in the lower sub-block BL2.

Meanwhile, in the right division block DBLC2 of the two division blocks DBLC, although not shown, an upper sub-block BL1D and a lower sub-block BL2D are stacked in this order from the top, and a shuttle layer BL3D is provided in each of the upper sub-block BL1D and the lower sub-block BL2D.

Each of the upper sub-block BL1D and the lower sub-block BL2D of the right division block DBLC2 is provided with the transfer mechanism 160 (see FIG. 18), like the upper sub-block BL1 of the right division block DBL2 described above. However, the transfer mechanism 160 provided in the right division block DBLC2 is different from the one provided in the right division block DBL2 described above in that it transfers the wafer W between processing modules within the right division block DBLC2 and a transit module TRS2 to be described later as well as between the transit block 110 of the interface block 12A and the processing modules within the right division block DBLC2 and between the processing modules within the right division block DBLC2 themselves.

In the right division block DBLC2, a space on the front side (negative X-axis side in the drawing) of the transfer space K4 in each of the upper sub-block BL1D and the lower sub-block BL2D is divided into the upper layer BL11 and the lower layer BL12 in which the developing modules DEV are provided, the same as in the upper sub-block BL1 described above.

Back to the description of the left division block DBLC1, the shuttle layer BL3C is provided on the rear side (positive X-axis side in the drawing) of the second transfer space K2 in each of the upper sub-block BL1C and the lower sub-block BL2C in such a manner as to be stacked on top of or under the heat treatment modules HT.

Each shuttle layer BL3C is provided with a shuttle transfer mechanism 150C. In the following description, the shuttle transfer mechanism 150C provided in the shuttle layer BL3C of the upper sub-block BL1C will sometimes be referred to as an upper shuttle transfer mechanism 150Ca, and the shuttle transfer mechanism 150C provided in the shuttle layer BL3C of the lower sub-block BL2C will sometimes be referred to as a lower shuttle transfer mechanism 150Cb.

Like the shuttle transfer mechanism 150 described above, the shuttle transfer mechanism 150C transfers the wafer W only linearly in the width direction (Y-axis direction in the drawing). In this example, the shuttle transfer mechanism 150C transfers the wafer W linearly in the width direction (Y-axis direction in the drawing) between a transit module TRS1 provided in the left division block DBL1 and a transit module TRS2 provided in the right division block DBL2.

To elaborate, the upper shuttle transfer mechanism 150Ca transfers the wafer W linearly in the width direction between the transit module TRS1 provided in the upper sub-block BL1C of the left division block DBLC1 and the transit module TRS2 provided in the upper sub-block BL1D of the right division block DBLC2. Further, the lower shuttle transfer mechanism 150Cb transfers the wafer W linearly in the width direction between the transit module TRS1 provided in the lower sub-block BL2C of the left division block DBLC1 and the transit module TRS2 provided in the lower sub-block BL2D of the right division block DBLC2.

Hereinafter, the transit module TRS1 provided in the upper sub-block BL1C will sometimes be referred to as an upper transit module TRS1a, and the transit module TRS2 provided in the upper sub-block BL1D will sometimes be referred to as an upper transit module TRS2a.

A linear transfer path of wafer W by the shuttle transfer mechanism 150C and the transit modules TRS1 and TRS2 are arranged so as to overlap with the processing modules within the processing block 11C when viewed from the top. For example, when the heat treatment module HT has both the hot plate and the cooling plate, the linear transfer path of the wafer W by the shuttle transfer mechanism 150C and the transit modules TRS1 and TRS2 are arranged to overlap with only the cooling plate of the heat treatment module HT, not the hot plate, when viewed from the top.

The transit module TRS1 is provided at, for example, an end portion of the left division block DBLC1 on the cassette block 10 side on the rear side (positive X-axis side in the drawing) of the second transfer space K2.

Further, the transit module TRS2 is provided at, for example, an end portion of the right division block DBLC2 on the cassette block 10 side on the rear side (positive X-axis side in the drawing) of the transfer space K4.

Meanwhile, in the right division block DBLC2, a shuttle layer BL3D is provided on the rear side (positive X-axis side in the drawing) of the transfer space K4 in each of the upper sub-block BL1D and the lower sub-block BL2D so as to be stacked on top of or under the heat treatment modules HT.

Each shuttle layer BL3D is provided with a shuttle transfer mechanism 150D. In the following description, the shuttle transfer mechanism 150D provided in the shuttle layer BL3D of the upper sub-block BL1D will sometimes be referred to as an upper shuttle transfer mechanism 150Da, and the shuttle transfer mechanism 150D provided in the shuttle layer BL3D of the lower sub-block BL2D will sometimes be referred to as a lower shuttle transfer mechanism 150Db.

Like the shuttle transfer mechanism 150 described above, the shuttle transfer mechanism 150D transfers the wafer W only linearly in the width direction (Y-axis direction in the drawing). In this example, the shuttle transfer mechanism 150D transfers the wafer W linearly in the width direction (Y-axis direction in the drawing) between the transit module TRS3 provided in the right division block DBLC2 and a transit module TRS4 provided in the left division block DBLC1.

To elaborate, the upper shuttle transfer mechanism 150Da transfers the wafer W linearly in the width direction between the transit module TRS3 provided in the upper sub-block BL1D of the right division block DBLC2 and the transit module TRS4 provided in the upper sub-block BL1C of the left division block DBLC1. Further, the lower shuttle transfer mechanism 150Db transfers the wafer W linearly in the width direction between the transit module TRS3 provided in the lower sub-block BL2D of the right division block DBLC2 and the transit module TRS4 provided in the lower sub-block BL2C of the left division block DBLC1.

Hereinafter, the transit module TRS3 provided in the upper sub-block BL1D will sometimes be referred to as an upper transit module TRS3a, and the transit module TRS4 provided in the upper sub-block BL1C will sometimes be referred to as an upper transit module TRS4a.

The linear transfer path of the wafer W by the shuttle transfer mechanism 150D and the transit modules TRS3 and TRS4 are arranged so as to overlap with the processing moules within the processing block 11C when viewed from the top. For example, when the heat treatment module HT has both a hot plate and a cooling plate, the linear transfer path of the wafer W by the shuttle transfer mechanism 150D and the transit modules TRS3 and TRS4 are arranged to overlap with only the cooling plate of the heat treatment module HT, not the hot plate, when viewed from the top.

The transit module TRS3 is provided at, for example, an end of the right division block DBLC2 on the interface block 12A side on the rear side (positive X-axis side in the drawing) of the transfer space K4.

Also, the transit module TRS4 is provided at, for example, an end of the left division block DBLC1 on the interface block 12A side on the rear side (positive X-axis side in the drawing) of the second transfer space K2.

When the processing block 11C is configured as described above, the transfer mechanism 185 of the interface block 12A transfers the wafer W between the transit module TRS3 and the transit block 110.

Furthermore, when the processing block 11C is configured as described above, the first transfer mechanism 40 of the cassette block 10 is configured to be able to transfer the wafer W to the transit module TRS1 as well.

When the processing block 11C is configured as described above, the wafer W is supported in the following order, for example, to be subjected to the resist film coating process, the exposure process, and so forth.

First transfer mechanism 40→transit module 31 of transit block 30→second transfer mechanism 70→resist film forming module COT in upper sub-block BL1C→second transfer mechanism 70→heat treatment module HT for PAB in upper sub-block BL1C→second transfer mechanism 70→upper transit module TRS4a→upper shuttle transfer mechanism 150Da→upper transit module TRS3a→transfer mechanism 185→transit module 111 in interface block 12A→third transfer mechanism 120→exposure apparatus

Furthermore, the wafer W is supported in the following order, for example, to be subjected to the PEB process, the developing process, and so forth.

Exposure apparatus→third transfer mechanism 120→transit module 111 of interface block 12A→transfer mechanism 160→heat treatment module HT for PEB in upper sub-block BL1D→transfer mechanism 160→developing module DEV in upper sub-block BL1D→transfer mechanism 160→heat treatment module HT for post-baking in upper sub-block BL1D→transfer mechanism 160→upper transit module TRS2a→upper shuttle transfer mechanism 150Ca→upper transit module TRS1a→first transfer mechanism 40

By using the processing block 11C as described above, it is possible to increase the number of processing modules mounted in the processing block 11C.

In addition, when the first transfer mechanism 40 transfers the wafer to/from the transit module TRS1 as well as the transit block 30, the following configuration may be adopted. That is, the first transfer mechanism 40 needs to be configured to transfer the wafer W to/from the transit block 30 only from one side (specifically, the rear side) in the depth direction (X-axis direction in the drawing), and the transit module TRS1 needs to be provided on the one side (specifically, the rear side) of the transit block 30. With this configuration, the transfer of the wafer W to/from the transit block 30 by the first transfer mechanism 40 and the transfer of the wafer W to/from the transit module TRS1 by the first transfer mechanism 40 can be performed in succession in a short time, so that throughput can be improved.

The substrate processing apparatus according to the present disclosure is also applicable to a processing apparatus for a processing target substrate other than the semiconductor wafer, such as a FPD (flat panel display) substrate.

In addition, the process performed on the wafer W by the processing module of the substrate processing apparatus may be to acquire an image for inspection.

It should be noted that the above-described exemplary embodiments are illustrative in all aspects and are not anyway limiting. The above-described exemplary embodiments may be omitted, replaced and modified in various ways without departing from the scope and the spirit of claims. For example, the constitutional elements of the above-described exemplary embodiments may be combined in various ways. From any of these various combinations, functions and effects for the respective constituent elements are naturally obtained, and other functions and other effects obvious to those skilled in the art are also obtained from the description of the present specification.

In addition, the effects described in the present specification are only explanatory or illustrative and are not limiting. That is, the technique according to the present disclosure may exhibit, together with or instead of the above-stated effects, other effects obvious to those skilled in the art from the description of the present specification.

In addition, the following configuration examples are also included in the technical scope of the present disclosure.

(1) A substrate processing apparatus, including:
a carry-in/out block having a container placement section in which multiple containers each configured to accommodate therein a substrate are placed; and
a processing block, disposed to be adjacent to the carry-in/out block in a width direction, having multiple processing modules each configured to perform a process on the substrate,
wherein the carry-in/out block further includes:
a transit block in which transit modules configured to deliver the substrate are provided on a processing block side to deliver the substrate to/from the processing block; and
a first transfer mechanism configured to transfer the substrate between the container placement section and the transit block,
the processing block further includes a second transfer mechanism configured to transfer the substrate between the transit block and the processing module, and
the first transfer mechanism has a support configured to support the substrate, and is configured to allow the substrate supported by the support to pass through the transit block in a depth direction intersecting with the width direction, when viewed from a top.

(2) The substrate processing apparatus described in (1),
wherein the first transfer mechanism performs a delivery of the substrate to/from the transit block only from the depth direction.

(3) The substrate processing apparatus described in (2), further including:
a first blower configured to supply a clean gas from above into a first transfer space, in which the first transfer mechanism is provided, of the carry-in/out,
wherein the first transfer mechanism performs the delivery of the substrate to/from the transit block only from a first side in the depth direction,
the first blower is configured to supply the clean gas only to a portion of the first transfer space on the first side in the depth direction with respect to the transit block, and
a portion of the first transfer space on a second side in the depth direction with respect to the transit block is filled with a storage section configured to accommodate an electrical component.

(4) The substrate processing apparatus described in any one of (1) to (3),
wherein in the carry-in/out block, the container placement section is provided on an opposite side to the processing block in the width direction.

(5) The substrate processing apparatus described in (4),
wherein the first transfer mechanism is configured to perform a delivery of the substrate to/from the container placement section from the processing block side in the width direction.

(6) The substrate processing apparatus described in (4) or (5),
wherein the first transfer mechanism further includes a first guide member configured to guide a movement of the support in a vertical direction; and a second guide member configured to guide a movement of the first guide member in the depth direction, and
a size of a gap between the container placement section and the transit block in the width direction is greater than a length of the first guide member and less than a length of the support.

(7) The substrate processing apparatus described in any one of (1) to (6),
wherein the second transfer mechanism performs a delivery of the substrate to/from the transit block from the width direction.

(8) The substrate processing apparatus described in any one of (1) to (7),
wherein the processing block is divided into multiple sub-blocks in a vertical direction,
each of the sub-blocks is equipped with the second transfer mechanism, and
the transit block is configured to deliver the substrate to/from the second transfer mechanisms of all of the multiple sub-blocks.

(9) The substrate processing apparatus described in any one of (1) to (8), further including:
an additional block provided at a side of the processing block on an opposite side to the carry-in/out block in the width direction; and
a second blower configured to supply a clean gas from above into a second transfer space, in which the second transfer mechanism is provided, of the processing block,
wherein a part of the second blower is stacked on the additional block.

(10) The substrate processing apparatus described in any one of (1) to (8),
wherein the processing block is divided into multiple division blocks in the width direction, and
each division block is provided with the multiple processing modules and a shuttle transfer mechanism configured to transfer the substrate only linearly in the width direction.

(11) The substrate processing apparatus described in (10),
wherein the processing block further includes an intermediate block between the neighboring division blocks,
the intermediate block includes the transit block, and
the shuttle transfer mechanism transfers the substrate linearly in the width direction between the transit blocks.

(12) The substrate processing apparatus described in (10),
wherein the multiple division blocks are arranged side by side in the width direction, and
the shuttle transfer mechanism transfers the substrate linearly in the width direction between the transit module within the division block provided with the shuttle transfer mechanism and the transit module within an additional division block adjacent to the division block provided with the shuttle transfer mechanism.

(13) The substrate processing apparatus described in (12),
wherein a linear transfer path of the substrate by the shuttle transfer mechanism and the transit module to/from which the shuttle transfer mechanism transfers the substrate overlaps with the processing module when viewed from the top.

(14) The substrate processing apparatus described in (12) or (13),
wherein the first transfer mechanism transfers the substrate to the transit module, which is provided within the division block on a carry-in/out block side in the width direction, to/from which the shuttle transfer mechanism transfers the substrate.

(15) The substrate processing apparatus described in (14),
wherein the first transfer mechanism performs a delivery of the substrate to/from the transit block only from one side in the depth direction, and
the transit module, to/from which the shuttle transfer mechanism transfers the substrate, within the division block on the carry-in/out block side in the width direction is provided on the one side more than the transit block of the carry-in/out block in the depth direction.

According to the exemplary embodiment, it is possible to suppress enlargement of the substrate processing apparatus that might accompany high throughput.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting. The scope of the inventive concept is defined by the following claims and their equivalents rather than by the detailed description of the exemplary embodiments. It shall be understood that all modifications and embodiments conceived from the meaning and scope of the claims and their equivalents are included in the scope of the inventive concept.

We claim:

1. A substrate processing apparatus, comprising:
a carry-in/out block having a container placement section in which multiple containers each configured to accommodate therein a substrate are placed; and
a processing block, disposed to be adjacent to the carry-in/out block in a width direction, having multiple processing modules each configured to perform a process on the substrate,
wherein the carry-in/out block further comprises:
a transit block in which transit modules configured to deliver the substrate are provided on a processing block side to deliver the substrate to/from the processing block; and
a first transfer mechanism configured to transfer the substrate between the container placement section and the transit block,
the processing block further comprises a second transfer mechanism configured to transfer the substrate between the transit block and the processing module, and
the first transfer mechanism has a support configured to support the substrate, and is configured to allow the substrate supported by the support to pass through the transit block in a depth direction intersecting with the width direction, when viewed from a top.

2. The substrate processing apparatus of claim 1,
wherein the first transfer mechanism performs a delivery of the substrate to/from the transit block only from the depth direction.

3. The substrate processing apparatus of claim 2, further comprising:
a first blower configured to supply a clean gas from above into a first transfer space, in which the first transfer mechanism is provided, of the carry-in/out,
wherein the first transfer mechanism performs the delivery of the substrate to/from the transit block only from a first side in the depth direction,
the first blower is configured to supply the clean gas only to a portion of the first transfer space on the first side in the depth direction with respect to the transit block, and
a portion of the first transfer space on a second side in the depth direction with respect to the transit block is filled with a storage section configured to accommodate an electrical component.

4. The substrate processing apparatus of claim 1,
wherein in the carry-in/out block, the container placement section is provided on an opposite side to the processing block in the width direction.

5. The substrate processing apparatus of claim 4,
wherein the first transfer mechanism is configured to perform a delivery of the substrate to/from the container placement section from the processing block side in the width direction.

6. The substrate processing apparatus of claim 4,
wherein the first transfer mechanism further comprises a first guide member configured to guide a movement of the support in a vertical direction; and a second guide member configured to guide a movement of the first guide member in the depth direction, and
a size of a gap between the container placement section and the transit block in the width direction is greater than a length of the first guide member and less than a length of the support.

7. The substrate processing apparatus of claim 1,
wherein the second transfer mechanism performs a delivery of the substrate to/from the transit block from the width direction.

8. The substrate processing apparatus of claim 1,
wherein the processing block is divided into multiple sub-blocks in a vertical direction,
each of the sub-blocks is equipped with the second transfer mechanism, and
the transit block is configured to deliver the substrate to/from the second transfer mechanisms of all of the multiple sub-blocks.

9. The substrate processing apparatus of claim 1, further comprising:
an additional block provided at a side of the processing block on an opposite side to the carry-in/out block in the width direction; and
a second blower configured to supply a clean gas from above into a second transfer space, in which the second transfer mechanism is provided, of the processing block,
wherein a part of the second blower is stacked on the additional block.

10. The substrate processing apparatus of claim 1,
wherein the processing block is divided into multiple division blocks in the width direction, and
each division block is provided with the multiple processing modules and a shuttle transfer mechanism configured to transfer the substrate only linearly in the width direction.

11. The substrate processing apparatus of claim 10,
wherein the processing block further comprises an intermediate block between the neighboring division blocks,
the intermediate block comprises the transit block, and
the shuttle transfer mechanism transfers the substrate linearly in the width direction between the transit blocks.

12. The substrate processing apparatus of claim 10,
wherein the multiple division blocks are arranged side by side in the width direction, and
the shuttle transfer mechanism transfers the substrate linearly in the width direction between the transit module within the division block provided with the shuttle transfer mechanism and the transit module within an additional division block adjacent to the division block provided with the shuttle transfer mechanism.

13. The substrate processing apparatus of claim 12,
wherein a linear transfer path of the substrate by the shuttle transfer mechanism and the transit module to/from which the shuttle transfer mechanism transfers the substrate overlaps with the processing module when viewed from the top.

14. The substrate processing apparatus of claim 12,
wherein the first transfer mechanism transfers the substrate to the transit module, which is provided within the division block on a carry-in/out block side in the width direction, to/from which the shuttle transfer mechanism transfers the substrate.

15. The substrate processing apparatus of claim 14,
wherein the first transfer mechanism performs a delivery of the substrate to/from the transit block only from one side in the depth direction, and
the transit module, to/from which the shuttle transfer mechanism transfers the substrate, within the division block on the carry-in/out block side in the width direction is provided on the one side more than the transit block of the carry-in/out block in the depth direction.
